(19) United States
(12) Patent Application Publication
(10) Pub. No.: US 2024/0234103 A1
(43) Pub. Date: Jul. 11, 2024

(54) RING ASSEMBLY AND SEMICONDUCTOR WAFER ETCHING DEVICE

(71) Applicant: Samsung Electronics Co., Ltd., Suwon-si (KR)

(72) Inventors: Hyunsu Hwang, Suwon-si (KR); Unbyoung Kang, Suwon-si (KR); Jumyong Park, Suwon-si (KR); Dongjoon Oh, Suwon-si (KR); Hyunchul Jung, Suwon-si (KR); Sanghoo Cho, Suwon-si (KR)

(21) Appl. No.: 18/404,423

(22) Filed: Jan. 4, 2024

(30) Foreign Application Priority Data
Jan. 10, 2023 (KR) 10-2023-0003442
Jun. 7, 2023 (KR) 10-2023-0073112

(51) Int. Cl. H01J 37/32

(52) U.S. Cl. CPC H01J 37/32642; H01J 37/32715; H01J 2237/334

(57) ABSTRACT

A ring assembly is used in a semiconductor wafer etching device in which a plasma gas flow stream line is not uniform and which surrounds a wafer support plate supporting a semiconductor wafer. The ring assembly includes: an edge ring protruding from at least one side of the semiconductor wafer to have an upper surface higher than an upper surface of the semiconductor wafer; and a shadow ring movable up and down above the edge ring and configured to be tilted with respect to the semiconductor wafer.

### CROSS-REFERENCE TO RELATED APPLICATIONS

This application claims benefit of priority to Korean Patent Application Nos. 10-2023-0003442 filed on Jan. 10, 2023 and 10-2023-0073112 filed on Jun. 7, 2023 in the Korean Intellectual Property Office, the disclosures of which are incorporated herein by reference in their entireties.

### BACKGROUND

The present inventive concept relates to a ring assembly and a semiconductor wafer etching device. More specifically, the present inventive concept relates to a ring assembly and a semiconductor wafer etching device for controlling an etching rate of a semiconductor wafer when a pump is installed in a chamber asymmetrically.

A semiconductor wafer etching device using plasma may form, for example, a through-silicon via (TSV) in a wafer. Such a semiconductor wafer etching device includes an edge ring or a shadow ring provided in an outer region of an edge of a substrate stage in order to obtain a uniform etching profile over the entire region of a wafer.

Even if RF plasma is provided uniformly, a plasma gas flow stream line may not be constant if, for example, a pump is designed to be asymmetrically disposed in a chamber. Specifically, non-uniform etching occurs in an edge region of a wafer because a flow stream line is stronger where the pump is placed.

When an imbalance occurs due to the plasma gas flow stream line within the chamber and a difference in imbalance increases, non-uniformity of an etching amount in the wafer edge region may increase.

Therefore, an apparatus and method to make the etching amount of a semiconductor wafer uniform overall, even when an imbalance occurs in the plasma gas flow stream line in the chamber would be desirable.

### SUMMARY

An aspect of the present inventive concept is to provide a ring assembly capable of performing uniform etching over the entire region of a semiconductor wafer, even when a plasma gas flow stream line is unbalanced in a processing chamber.

Another aspect of the present inventive concept is to provide a ring assembly capable of performing uniform etching over the entire region of a semiconductor wafer by adjusting tilting of an edge ring and a height of a shadow ring.

Another aspect of the present inventive concept is to provide a semiconductor wafer etching device to which a ring assembly is applied to make a plasma gas flow stream line uniform when the plasma gas flow stream line is unbalanced in a processing chamber.

Another aspect of the present inventive concept is to provide a semiconductor wafer plasma etching device including an edge ring and a shadow ring having improved shapes to adjust an overall etching rate of a wafer edge region.

According to an aspect of the present inventive concept, a ring assembly is provided surrounding a wafer support plate, the wafer support plate being configured to support a semiconductor wafer, the ring assembly including an edge ring protruding from at least one side of the semiconductor wafer to have an upper surface higher than an upper surface of the semiconductor wafer; and a shadow ring movable up and down above the edge ring and configured to be tilted with respect to the semiconductor wafer.

According to another aspect of the present inventive concept, a ring assembly is provided surrounding a wafer support plate, the wafer support plate being configured to support a semiconductor wafer, the ring assembly including an edge ring protruding to have an upper surface higher than an upper surface of the semiconductor wafer; and a shadow ring movable up and down above the edge ring and tilted with respect to the semiconductor wafer.

According to another aspect of the present inventive concept, a semiconductor wafer etching device includes a processing chamber; a substrate support plate on which a semiconductor wafer is seated in the processing chamber; an edge ring on the substrate support plate to surround the semiconductor wafer, the edge ring having an upper surface protruding to be higher than an upper surface of the semiconductor wafer; a shadow ring above the edge ring and having a gap with the protruding upper surface of the edge ring; and a lift pin installed to move the shadow ring up and down, supporting the shadow ring in at least two points, and configured to lift the shadow ring in at least one point of the at least two points.

According to another aspect of the present inventive concept, a ring assembly is provided surrounding a wafer support plate, the ring assembly including an edge ring, wherein a height of a first portion of the edge ring is different from a height of a second portion of the edge ring; and a shadow ring movable up and down above the edge ring and configured to be tilted with respect to a plane of the wafer support plate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic cross-sectional view of a semiconductor wafer etching device according to an example of the present inventive concept;

FIG. 2 is a schematic perspective view illustrating a ring assembly according to an example of the present inventive concept;

FIG. 3 is a cross-sectional view taken along line I-I′ of FIG. 2;

FIG. 4 is an enlarged cross-sectional view of portion A of FIG. 3 when the shadow ring is in a first position;

FIG. 5 is an enlarged cross-sectional view of the portion A of FIG. 3 when the shadow ring is in a second position;

FIG. 6 is an enlarged cross-sectional view of the portion A of FIG. 3 when the shadow ring is in a third position;

FIG. 7 is a schematic cross-sectional view illustrating a position of a shadow ring when an asymmetric plasma gas flow stream line is unbalanced;

FIG. 8 is a diagram schematically illustrating etching experiment results of a wafer on which etching is performed with a ring assembly of the related art in a state in which an asymmetric plasma gas flow stream line is formed in a processing chamber;

FIG. 9 is a diagram schematically illustrating etching experiment results of a wafer on which etching is performed with a ring assembly having a structure of a modified edge ring of the present inventive concept in a state in which an asymmetrical plasma gas flow stream line is formed in a processing chamber;

FIG. 10 is a diagram schematically illustrating etching experiment results of a wafer on which etching is performed with a ring assembly having a structure of a modified edge ring and a modified shadow ring according to the present inventive concept in a state in which an asymmetrical plasma gas flow stream line is formed in a processing chamber;

FIG. 11 is a graph illustrating the etching amount experiment results of FIGS. 8 to 10; and

FIG. 12 is a graph illustrating a decrease in etching amount in a wafer edge region according to a height of an edge ring and a gap between a shadow ring according to the present inventive concept.

FIG. 13 illustrates a method of etching a semiconductor wafer according to an embodiment.

### DETAILED DESCRIPTION

Hereinafter, embodiments of the present inventive concept will be described in detail with reference to the accompanying drawings.

The embodiments of the present inventive concept may be modified into other forms and are provided so that this disclosure will be thorough and complete and will fully convey the scope of the invention to those of ordinary skill in the art. In the drawings, the shapes and dimensions of elements may be exaggerated for clarity, and like reference numerals denote like elements.

In the present inventive concept, the meaning of a “connection” of a component to another component includes an indirect connection through another element as well as a direct connection between two components. In addition, in some cases, the meaning of “connection” includes all “electrical connections.”

It may be understood that when an element is referred to with “first” and “second,” the element is not limited thereby. These terms may be used only for a purpose of distinguishing the element from the other elements, and so not necessarily limit the sequence or importance of the elements. In some cases, a first element may be referred to as a second element without departing from the scope of the inventive concept. Similarly, a second element may also be referred to as a first element.

The terms used in the present inventive concept are used to simply describe an example and are not intended to limit the present inventive concept. A singular term includes a plural form unless otherwise indicated.

### Semiconductor Wafer Etching Device

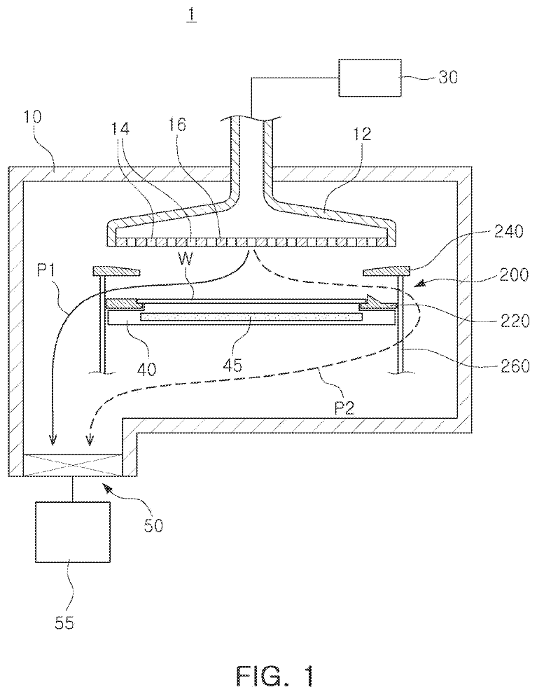

FIG. 1 is a schematic cross-sectional view of a semiconductor wafer etching device according to an example of the present inventive concept.

Referring to FIG. 1, a semiconductor wafer etching device 1 of the present inventive concept includes a processing chamber 10, a substrate support plate 40, a ring assembly 200, and a lift pin 260.

The semiconductor wafer etching device 1 may be a device for etching a thin film disposed on a semiconductor wafer W. For example, the semiconductor wafer etching device 1 may be a chemical vapor deposition (CVD) device, an atomic layer deposition (ALD) device, or a dry etching device for etching thin films through gas injection, and may be applied to any device for etching thin films.

The semiconductor wafer W processed by the semiconductor wafer etching device 1 is loaded to or unloaded from the substrate support plate 40. The semiconductor wafer W may be, for example, a silicon wafer used for manufacturing a semiconductor integrated circuit (IC).

In the processing chamber 10, a pumping port 50 is located asymmetrically on one side of the processing chamber 10 on the whole. The pumping port 50 interworks with an external pump 55 to create a gas flow within the processing chamber 10.

The processing chamber 10 may provide a space in which a process is performed. The processing chamber 10 may include an upper wall, a side wall, and a lower wall, and although not shown, a passage through which semiconductor wafers W are carried in and out may be provided on one or more sides of the processing chamber 10.

A gas spraying unit 12 may be disposed above the substrate support plate 40 to face the substrate support plate 40 within the processing chamber 10. The gas spraying unit 12 is connected to a gas supply unit 30 and distributes a process gas supplied from the gas supply unit 30 to provide the distributed gas to an upper surface of the loaded semiconductor wafer W. The gas spraying unit 12 may be, for example, a shower head, and includes a spraying plate 16 having a plurality of spraying holes 14 through which the process gas is sprayed.

The spray holes 14 may be radially arranged based on the center of the gas spraying unit 12. A diffusion plate for distributing the process gas may be further provided in the gas supply unit 30 according to some embodiments.

The semiconductor wafer W is seated on the substrate support plate 40 (e.g., wafer support plate) in the processing chamber 10. An internal electrode 45 is included in the substrate support plate 40, and RF power may be supplied from a power supply unit (not illustrated).

The substrate support plate 40 may include a heater and may be an electric static chuck (ESC). A heat conductor, such as a hot wire, may be included therein, and a process temperature may be adjusted thereby. The substrate support plate 40 may be formed of or include, for example, aluminum nitride (AlN), but is not limited thereto.

When RF power is supplied into the processing chamber 10 and an electric field is generated due to a voltage difference between lower and upper portions of the semiconductor wafer W, plasma is generated in a process region in which an etching process is performed on the semiconductor wafer W.

In the processing chamber 10, since at least a portion of the process gas is converted into plasma, the process gas is activated to promote a reaction on the semiconductor wafer W, and when a distribution of the electric field around the semiconductor wafer W within the process region of the semiconductor wafer W is uniform, the etching process may be uniformly performed on the entire semiconductor wafer W.

However, since the pumping port 50 is formed on one side of the processing chamber 1 (e.g., the pumping port 50 is asymmetrically positioned with respect to the center of the processing chamber 10), a plasma gas flow stream line in the semiconductor wafer W is not uniform. When the pumping port 50 is formed on one side of the processing chamber 1, a plasma gas flow stream line P1 in the position of the pumping port 50 forms a fast flow, and a plasma gas flow stream line P2 in a position on the opposite side distant from the position of the pumping port 50 has a relatively slow flow compared to the plasma gas flow stream line P1 in the position of the pumping port 50.

When the fast flow is formed in the plasma gas flow stream line P1 in the position of the pumping port 50, an etching amount thereof is greater than an etching amount of the plasma gas flow stream line P2 on the opposite side distant from the position of the pumping port 50 and having a relatively slow flow.

In order to make the non-uniform etching amount on the entire upper surface of the semiconductor wafer W uniform on the entire upper surface of the semiconductor wafer W, the ring assembly 200 of the present inventive concept is proposed. This will be described in detail below.

Configurations, structures, and arrangements of the processing chamber 10, the gas spraying unit 12, the substrate support plate 40, and the gas supply unit 30 of the semiconductor wafer etching device 1 illustrated in FIG. 1 are examples and may be variously changed in embodiments.

### Ring Assembly

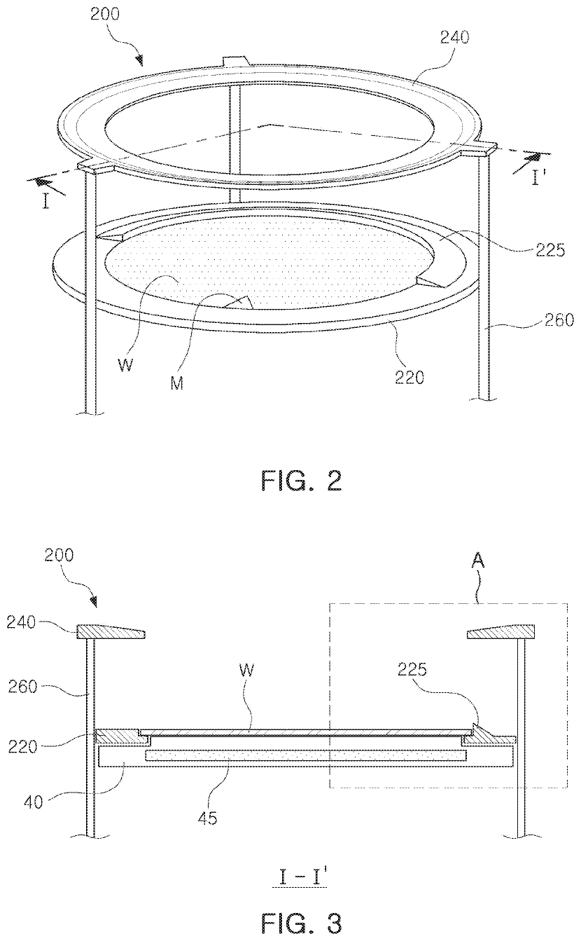

FIG. 2 is a schematic perspective view illustrating a ring assembly according to an example of the present inventive concept.

Referring to FIG. 2, the ring assembly 200 according to an example of the present inventive concept includes an edge ring 220 and a shadow ring 240. The ring assembly 200 is used in the semiconductor wafer etching device 1 in which the plasma gas flow stream lines P1 and P2 are not uniform. The ring assembly 200 surrounds the wafer support plate 40 supporting the semiconductor wafer W.

The edge ring 220 is disposed on the substrate support plate 40 and surrounds the semiconductor wafer W, and an upper surface of at least one side of the edge ring 220 protrudes to be higher than an upper surface of the semiconductor wafer W.

A protrusion 225 on at least one side and having an upper surface higher than the upper surface of the semiconductor wafer W is disposed in a position in which the plasma gas flow stream line P1 is relatively fast, to generate resistance in the high flow rate plasma gas flow stream line P1 to retard the flow so that the etching proceeds slowly. For example, the plasma gas flow stream line P1 in a first region of the edge ring is faster than the plasma gas flow stream line P2 in a second region of the edge ring. The edge ring 220 includes the protrusion 225 in the first region thereof. The protrusion 225 of the edge ring 220 is higher than a portion of the edge ring 220 that does not include the protrusion.

For example, an uppermost height of the edge ring 220 at a first location along the circumference of the edge ring may be different from an uppermost height of the edge ring 220 at a second location along the circumference of the edge ring

The shadow ring 240 is disposed to be movable up and down on the top of the edge ring 220 and is tilted in an upper portion of at least one side of the semiconductor wafer W. For example, the shadow ring 240 is configured to be tilted with respect to a plane of the semiconductor wafer W or a plane of the substrate support plate 40.

For example, the shadow ring 240 may be movable up and down above the edge ring 220 and may be configured to be tilted with respect to a plane of the wafer support plate. For example, a gap between the shadow ring 240 and the upper surface of the edge ring 220 in a region above the first location of the edge ring may be greater than a gap between the shadow ring 240 and the upper surface of the edge ring 220 in a region above the second location of the edge ring.

The shadow ring 240 is installed to be movable up and down by a lift pin 260. The lift pin 260 may be moved up and down, for example, by an actuator. Although three lift pins 260 are illustrated in the embodiment of FIG. 2, the number is not particularly limited as long as the shadow ring 240 is supported in at least two points.

When the shadow ring 240 is tilted as a whole by moving only the lift pin 260 disposed in the fast position of the plasma gas flow stream line P1 upwardly, resistance to the fast flow of the plasma gas flow stream line P1 may be generated, so that plasma gas is uniformly distributed throughout the semiconductor wafer W and uniform etching may be achieved.

The edge ring 220 has a protrusion 225 in at least one portion of the entire ring, and in the embodiment of FIG. 2, the protrusion 225 protrudes in a direction opposite to a marker M marked on the semiconductor wafer. For example, the wafer may be positioned such that the marker M is at a position opposite to the position of the protrusion 225 as shown, e.g., in FIG. 2. The protrusion 225 is not particularly limited in number or shape, as long as the protrusion has a position or shape that creates resistance to a flow rate in a position corresponding to the plasma gas flow stream line P1 having a high flow rate.

In order to measure the etching amount distribution in the entire semiconductor wafer W, the marker M marked on the semiconductor wafer W may be disposed in a position opposite to a position in which the plasma gas flow stream line P1 is fast.

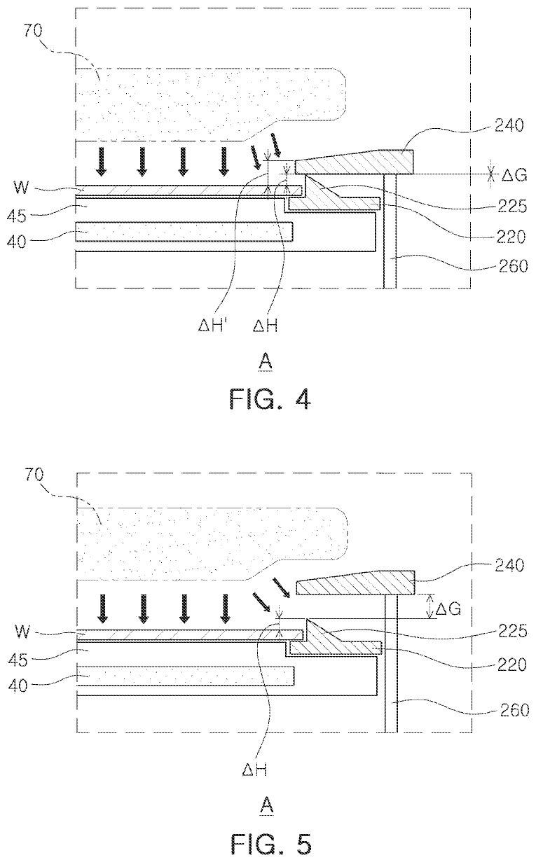

After determining a height difference ΔH between an upper surface of the protrusion 225 of the edge ring 220 and the upper surface of the semiconductor wafer W (see, e.g., FIG. 4), an etching distribution of the semiconductor wafer W may be made more uniform by further finely adjusting the shadow ring 240.

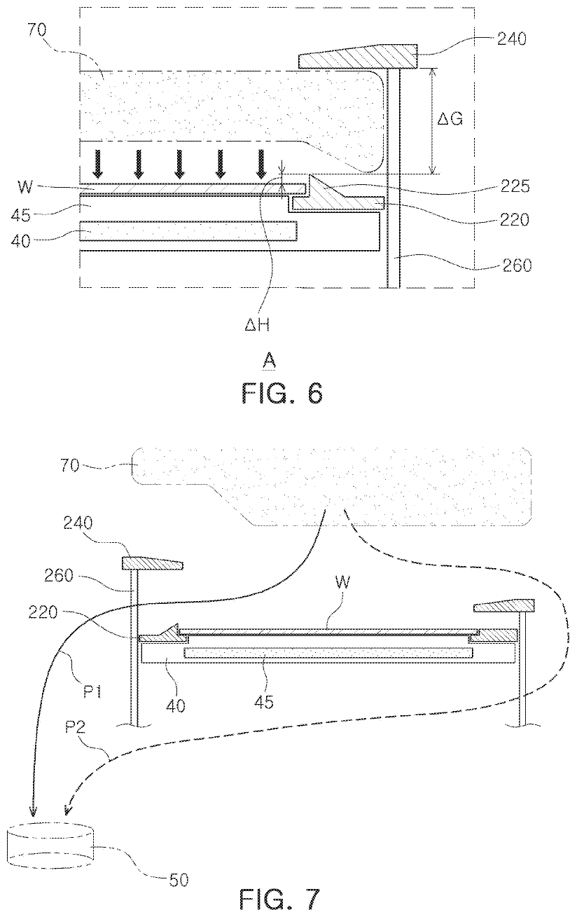

FIG. 3 is a cross-sectional view taken along line I-I′ of FIG. 2. FIG. 4 is an enlarged cross-sectional view of portion A of FIG. 3 when the shadow ring is in a first position, FIG. 5 is an enlarged cross-sectional view of the portion A of FIG. 3 when the shadow ring is in a second position, and FIG. 6 is an enlarged cross-sectional view of portion A of FIG. 3 when the shadow ring is in a third position.

Referring to FIGS. 3 to 6, after the height difference ΔH between the upper surface of the protrusion 225 of the edge ring 220 and the upper surface of the semiconductor wafer W is determined, a distribution of a plasma gas 70 may be known according to the height of the shadow ring 240.

When a distance from a lower surface of the shadow ring 240 to the uppermost surface of the edge ring 220 is a gap ΔG, FIG. 4 illustrates the position of the shadow ring 240 when the gap ΔG is zero.

As illustrated in FIG. 4, when the shadow ring 240 is in the position in which the gap ΔG is 0, the protrusion 225 of the edge ring 220 may be understood as effectively including a thickness of the shadow ring 240, so that an effect of increasing a height difference ΔH′ between the upper surface of the protrusion 225 of the edge ring 220 and the upper surface of the semiconductor wafer W is obtained. As the upper surface of the protrusion 225 of the edge ring 220 effectively includes the thickness of the shadow ring 240, the height difference ΔH' from the upper surface of the semiconductor wafer W increases. Due thereto, the flow of the plasma gas 70 has less effect on the edge of the semiconductor wafer W, so that the etching amount may be further reduced to some extent.

FIG. 5 illustrates a position of the shadow ring 240 when a gap ΔG is 0 mm≤ΔG≤10.4 mm. When the shadow ring 240 is located in the range of 0 mm≤ΔG≤10.4 mm, the shadow ring 240 further interrupts the flow of the plasma gas. Due to the height difference ΔH between the upper surface of the protrusion 225 of the edge ring 220 and the upper surface of the semiconductor wafer W, the etching amount of the edge of the semiconductor wafer W may be reduced and the etching amount may be uniform in the entire semiconductor wafer W.

FIG. 6 illustrates the position of the shadow ring 240 when the gap ΔG is ΔG>10.4 mm. When the shadow ring 240 is located at ΔG>10.4 mm, the flow of the plasma gas 70 rather flows between the edge ring 220 and the shadow ring 240, thereby increasing the etching amount at the edge of the semiconductor wafer W.

Referring to FIGS. 4 to 6, when an imbalance in the etching amount occurs in the semiconductor wafer W between a position in which the plasma gas flow stream line P1 is fast and a position in which the plasma gas flow stream line P2 is slow, the position of the shadow ring 240 is adjusted in the position in which the plasma gas flow stream line P1 is fast, while the shadow ring 240 in the position in which the plasma gas flow stream line P2 is slow is fixed, thereby making the etching amount uniform in the entire semiconductor wafer W.

FIG. 7 is a schematic cross-sectional view illustrating a position of a shadow ring when an asymmetrical plasma gas flow stream line is unbalanced.

Referring to FIG. 7, in a state in which the height difference ΔH between the upper surface of the protrusion 225 of the edge ring 220 and the upper surface of the semiconductor wafer W is determined, when the shadow ring 240 is tilted as a whole by increasing the height of the lift pin 260 located on a side of the pumping port 50, the plasma gas 70 may be distributed more in the position in which the plasma gas flow stream line P2 is slow than in the position in which the plasma gas flow stream line P1 is fast, so that the semiconductor wafer W within the processing chamber 10 in which a non-uniform gas flow stream line occurs may be uniformly etched.

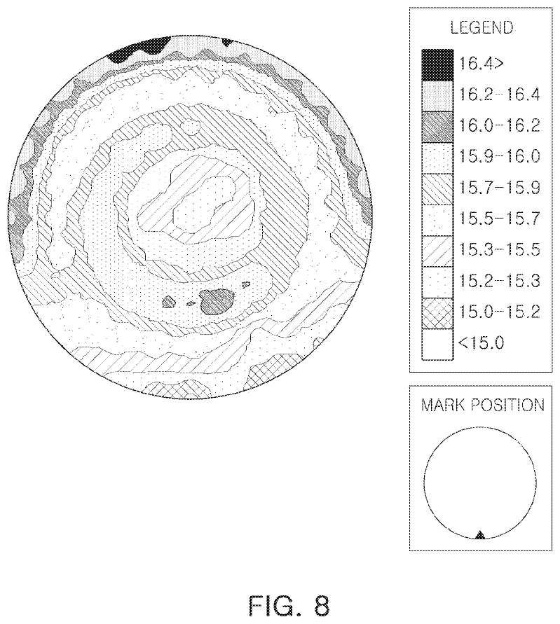

FIG. 8 is a diagram schematically illustrating etching experiment results of a wafer on which etching is performed with a ring assembly of the related art in a state in which an asymmetrical plasma gas flow stream line is formed in a processing chamber.

Referring to FIG. 8, a resultant value is obtained as an etching process is performed in a state in which there is no height difference ΔH between the upper surface of the protrusion 225 of the edge ring 220 and the upper surface of the semiconductor wafer W and the shadow ring 240 is not tilted as a whole.

The position in which the plasma gas flow stream line P1 is fast is located on the opposite side of the position of the marker (M). That is, the etching amount in the position in which the pumping port 50 is located is 16.4 μm or more at the maximum, and the etching amount in the position of the marker M where the plasma gas flow stream line P2 is slow is 15.0 μm or less.

That is, the maximum etching amount difference between the position in which the pumping port 50 is located and the opposite position is about 1.4 μm or more due to the difference in flow rate of the plasma gas flow stream lines.

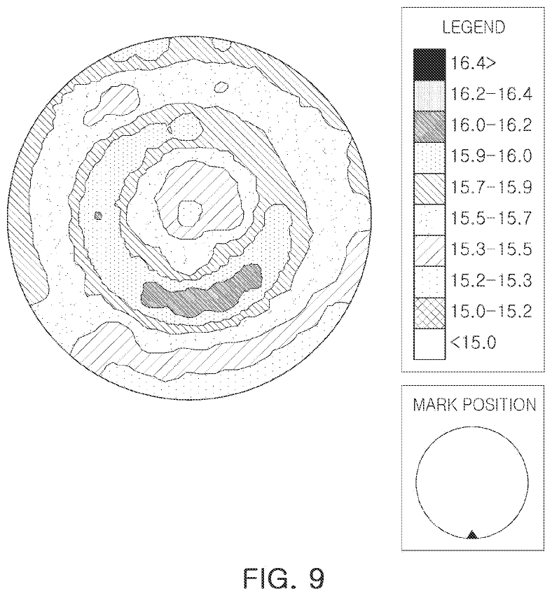

FIG. 9 is a diagram schematically illustrating etching experiment results of a wafer on which etching is performed with a ring assembly having a structure of the modified edge ring 220 of the present inventive concept in a state in which an asymmetrical plasma gas flow stream line is formed in a processing chamber.

The position in which the plasma gas flow stream line P1 is fast is the position opposite to the position of the marker M. In the present embodiment, the height difference ΔH between the upper surface of the protrusion 225 of the edge ring 220 and the upper surface of the semiconductor wafer W is fixedly set to 3 mm.

When the protrusion 225 of the edge ring 220 is set as above, the etching amount is up to 16 μm where the pumping port 50 is located, and the etching amount in the position of the marker M where the plasma gas flow stream line P2 is slow is 15.2 μm.

That is, when the protrusion 225 is formed on the edge ring 220, the difference in the maximum etching amount between the position in which the pumping port 50 is located and the opposite position is 0.8 μm due to the difference in flow rate of the plasma gas flow stream lines.

It can be seen that the difference in the maximum etching amount of the embodiment of FIG. 9 is reduced by 0.6 compared to the embodiment of FIG. 8.

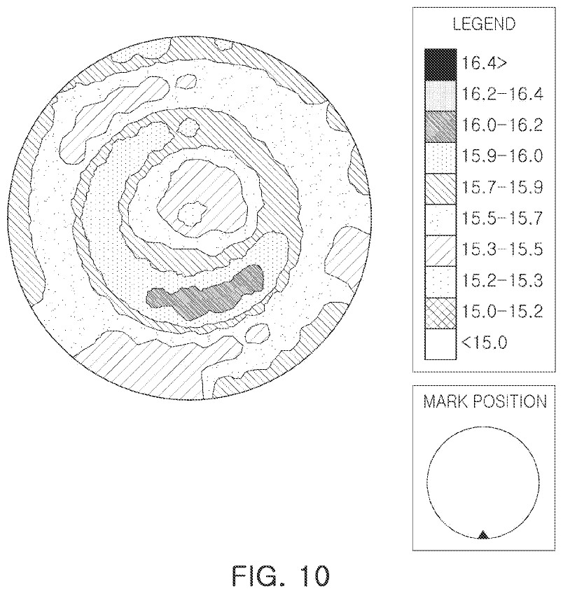

FIG. 10 is a diagram schematically illustrating etching experiment results of a wafer on which etching is performed with a ring assembly having a structure of a modified edge ring and a modified shadow ring according to the present inventive concept in a state in which an asymmetrical plasma gas flow stream line is formed in a processing chamber.

The position in which the plasma gas flow stream line P1 is fast is the position opposite to the position of the marker M. In the present embodiment, when the gap ΔG is a distance from a lower surface of the shadow ring 240 to the uppermost surface of the edge ring 220, a result obtained by performing etching after the gap ΔG is adjusted to 2.8 mm by raising the lift pin 260 in the position in which the pumping port 50 is disposed is shown.

When the shadow ring 240 is set to be tilted as above by raising the lift pin 260, the etching amount in the position in which the pumping port 50 is located is 15.9 μm at most, and the etching amount in the position of the marker M in which the plasma gas flow stream line P2 is slow is 15.4 μm.

That is, when the protrusion 225 is formed on the edge ring 220, the maximum difference in the etching amount between the position in which the pumping port 50 is located and the opposite position is 0.5 μm due to the difference in flow rate of the plasma gas flow stream lines. Compared to the embodiment of FIG. 9, it can be seen that the difference in etching amount of the entire semiconductor wafer W is reduced, resulting in overall uniform etching.

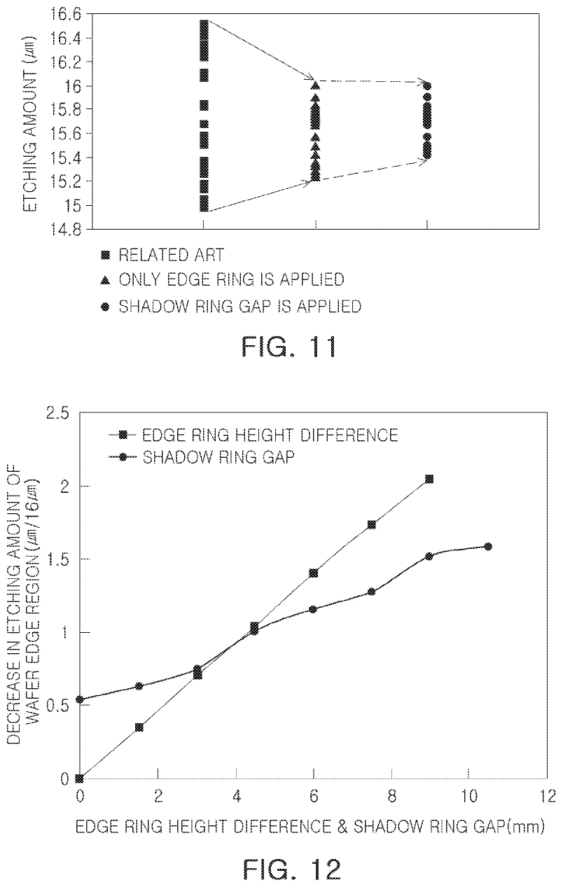

FIG. 11 is a graph illustrating the etching amount experiment results of FIGS. 8 to 10.

FIG. 11 is a graph qualitatively illustrating FIGS. 8 to 10. All of FIGS. 8 to 10 show the graphs of experiment results in a state in which the etching amount in the semiconductor wafer W is unbalanced in the position in which the plasma gas flow stream line P1 is fast and in the position in which the plasma gas flow stream line P2 is slow because of the asymmetrical position of the pumping port 50 in the processing chamber 10.

FIG. 11 illustrates that the maximum difference in etching amount is about 1.4 μm (16.4 μm−15 μm) when the etching process is performed in a state in which there is no height difference ΔH between the upper surface of the protrusion 225 of the edge ring 220 of the ring assembly 200 of the related art and the upper surface of the semiconductor wafer W and the shadow ring 240 is not tilted on the whole.

In addition, in the etching experiment result of the wafer etched with the ring assembly having the structure of the modified edge ring 220 of the present inventive concept in a state in which the asymmetrical plasma gas flow stream line of FIG. 9 is formed in the processing chamber, the maximum difference in etching amount is about 0.8 μm (16 μm−15.2 μm).

In addition, in the etching experiment result of the semiconductor wafer in the case of FIG. 10 in which the shadow ring 240 is set to be tilted by raising the lift pin 260 together with the edge ring of FIG. 9, the maximum difference in etching amount is about 0.5 μm (15.9 μm−15.4 μm).

A uniform distribution may be made using only the edge ring 220, and in addition, the maximum difference in etching amount may be more finely adjusted through fine adjustment of the shadow ring 240.

However, the height difference ΔH of the edge ring 220 cannot be infinitely increased and is limited by mechanical limitations of wafer loading, and the gap ΔG of the shadow ring 240 cannot be infinitely increased, and when the gap ΔG exceeds a certain range, the decrease in the etching amount is no longer achieved.

FIG. 12 is a graph illustrating a decrease in etching amount in a wafer edge region according to a height of an edge ring and according to a gap between a shadow ring and the edge ring according to the present inventive concept.

Referring to FIG. 12, when the height difference ΔH of the edge ring 220 increases, the decrease in the etching amount of the wafer edge region increases relatively linearly. However, when ΔH exceeds 12 mm, interference occurs when loading the semiconductor wafer W, and thus, ΔH needs to be limited to 12 mm or less.

In addition, when the gap ΔG of the shadow ring 240 exceeds 10.4 mm, the decrease in etching amount is no longer effective. Therefore, ΔG needs to be limited to 10.4 mm or less.

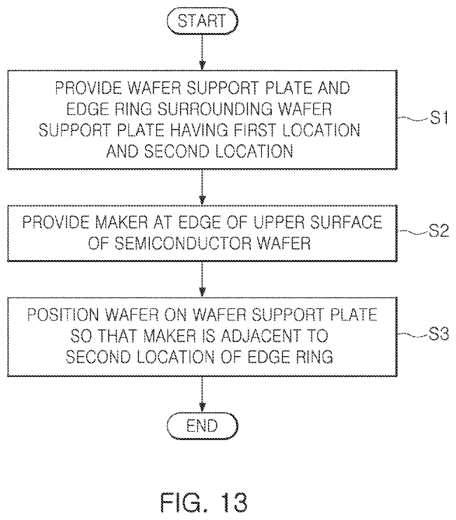

FIG. 13 illustrates a method of etching a semiconductor wafer according to an embodiment.

A wafer support plate and an edge ring surrounding the wafer support plate are provided (S1). The uppermost height of the edge ring at a first location along the circumference of the edge ring is different from the uppermost height of the edge ring at a second location along the circumference of the edge ring. A marker may be provided at an edge of the upper surface of the semiconductor wafer (S2).

The semiconductor wafer may be positioned on the wafer support plate so that the marker is adjacent to the second location of the edge ring (S3). However, the inventive concept is not limited thereto, and a semiconductor wafer without a marker may be positioned on the wafer support plate.

According to the ring assembly and the semiconductor wafer etching device of the present inventive concept, even when the plasma gas flow stream line is not constant as the pump is designed to be asymmetrically disposed in the chamber, uniform etching may be obtained over the entire region of the semiconductor wafer.

While example embodiments have been illustrated and described above, it will be apparent to those skilled in the art that modifications and variations could be made without departing from the scope of the present inventive concept as defined by the appended claims.

What is claimed is:

1. A ring assembly surrounding a wafer support plate, the wafer support plate being configured to support a semiconductor wafer, the ring assembly comprising:
an edge ring protruding from at least one side of the semiconductor wafer to have an upper surface higher than an upper surface of the semiconductor wafer; and
a shadow ring movable up and down above the edge ring and configured to be tilted with respect to the semiconductor wafer.

2. The ring assembly of claim 1, wherein
the ring assembly is used in a semiconductor wafer etching device in which a plasma gas flow stream line is not uniform so that the plasma gas flow stream line in a first region of the edge ring is faster than the plasma gas flow stream line in a second region of the edge ring,
the edge ring includes a protrusion in the first region, and
the protrusion of the edge ring is higher than a portion of the edge ring that does not include the protrusion.

3. The ring assembly of claim 1, wherein
the ring assembly is used in a semiconductor wafer etching device in which a plasma gas flow stream line is not uniform so that the plasma gas flow stream line in a first region of the shadow ring is faster than the plasma gas flow stream line in a second region of the shadow ring, and
a gap between the shadow ring and the upper surface of the edge ring in the first region is greater than a gap between the shadow ring and the upper surface of the edge ring in the second region.

4. The ring assembly of claim 1, wherein ΔH is 12 mm or less, in which ΔH is a height difference between an uppermost surface of the edge ring and the upper surface of the semiconductor wafer.

5. The ring assembly of claim 4, wherein ΔG is 10.4 mm or less, in which ΔG is a distance from the uppermost surface of the edge ring to a lower surface of the shadow ring.

6. A ring assembly surrounding a wafer support plate, the wafer support plate being configured to support a semiconductor wafer, the ring assembly comprising:
an edge ring protruding to have an upper surface higher than an upper surface of the semiconductor wafer; and
a shadow ring movable up and down above the edge ring and tilted with respect to the semiconductor wafer.

7. The ring assembly of claim 6, wherein
the ring assembly is used in a semiconductor wafer etching device in which a pumping port is asymmetrically disposed, and
a height of the upper surface of the edge ring in a first position corresponding to a position of the pumping port is higher than a height of the upper surface of the edge ring in a second position different from the first position.

8. The ring assembly of claim 6, wherein
he ring assembly is used in a semiconductor wafer etching device in which a pumping port is asymmetrically disposed, and
a height of the shadow ring in a first position corresponding to the position of the pumping port is higher than a height of the shadow ring in a second position different from the first position.

9. The ring assembly of claim 6, wherein
the ring assembly is used in a semiconductor wafer etching device in which a pumping port is asymmetrically disposed so that a plasma gas flow stream line in a first region of the edge ring is faster than the plasma gas flow stream line in a second region of the edge ring, and
the upper surface of the edge ring is higher than the upper surface of the semiconductor wafer in the first region, and
a gap between the shadow ring and the upper surface of the edge ring in the first region is larger than a gap between the shadow ring and the upper surface of the edge ring in the second region.

10. The ring assembly of claim 6, wherein ΔH is 12 mm or less, in which ΔH is a height difference between an uppermost surface of the edge ring and the upper surface of the semiconductor wafer.

11. The ring assembly of claim 10, wherein ΔG is 10.4 mm or less, in which ΔG is a distance from the uppermost surface of the edge ring to a lower surface of the shadow ring.

12. A semiconductor wafer etching device comprising:
a processing chamber;
a substrate support plate on which a semiconductor wafer is seated in the processing chamber;
an edge ring on the substrate support plate to surround the semiconductor wafer, the edge ring having an upper surface protruding to be higher than an upper surface of the semiconductor wafer;
a shadow ring above the edge ring and having a gap with the protruding upper surface of the edge ring; and
a lift pin installed to move the shadow ring up and down, supporting the shadow ring in at least two points, and configured to lift the shadow ring in at least one point of the at least two points.

13. The semiconductor wafer etching device of claim 12, wherein
a pumping port is formed asymmetrically on one side in the processing chamber, and
a height of the upper surface of the edge ring in a first position corresponding to the position of the pumping port is greater than a height of the upper surface of the edge ring in a second position different from the first position.

14. The semiconductor wafer etching device of claim 12, wherein
a pumping port is formed asymmetrically on one side in the processing chamber, and
a height of the shadow ring in a first position corresponding to the position of the pumping port is greater than a height of the shadow ring in a second position different from the first position.

15. The semiconductor wafer etching device of claim 12, wherein
a pumping port is formed asymmetrically on one side in the processing chamber so that a plasma gas flow stream line in a first region of the edge ring is faster than the plasma gas flow stream line in a second region of the edge ring,
the upper surface of the edge ring is higher than the upper surface of the semiconductor wafer in the first region, and
a gap between the shadow ring and the upper surface of the edge ring in the first region is larger than a gap between the shadow ring and the upper surface of the edge ring in the second region.

16. The semiconductor wafer etching device of claim 12, wherein ΔH is 12 mm or less, in which ΔH is a height difference between an uppermost surface of the edge ring and the upper surface of the semiconductor wafer.

17. The semiconductor wafer etching device of claim 16, wherein ΔG is 10.4 mm or less, in which ΔG is a distance from the uppermost surface of the edge ring to a lower surface of the shadow ring.

18. The semiconductor wafer etching device of claim 12, wherein
a pumping port is formed asymmetrically on one side in the processing chamber, and
the shadow ring is tilted with respect to the semiconductor wafer.

19. The semiconductor wafer etching device of claim 12, wherein
a pumping port is formed asymmetrically on one side in the processing chamber, and
a plasma gas flow stream line in the position of the pumping port has a higher flow rate than a plasma gas flow stream line in a position in which the pumping port is not located.

20. The semiconductor wafer etching device of claim 12, further comprising an actuator configured to control the lift pin to move up and down.
